(19) United States
(12) Patent Application Publication
(10) Pub. No.: US 2016/0165750 A1
(43) Pub. Date: Jun. 9, 2016

(54) THERMAL MODULE AND ELECTRONIC DEVICE HAVING THE THERMAL MODULE

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: DE-HUA TANG, Shenzhen (CN); JUN-XIONG ZHANG, Shenzhen (CN)

(21) Appl. No.: 14/790,704

(22) Filed: Jul. 2, 2015

(30) Foreign Application Priority Data
Dec. 3, 2014 (CN) 201410722084.X

(51) Int. Cl. H05K 7/20

(52) U.S. Cl. CPC H05K 7/20136

(57) ABSTRACT

A thermal module includes a shell, a plurality of fans assembled in the shell, and a plurality of louvers. The shell defines a plurality of openings corresponding to the fans. Each louver includes a frame coupled to one of the vents and a plurality of louver boards. A side edge of each louver board extends outward forming a shaft rotatably coupled to two opposite sides of the frame. The gravity center of the frame is configured adjacent to an end of the frame, which is away from the shaft.

### FIELD

The subject matter herein generally relates to a thermal module and an electronic device having the thermal module.

### BACKGROUND

Fans of an electronic device can have a number of louver boards to prevent hot gas recirculation. The louver boards are opened by the airflow when the fans are operated and are closed by gravity when the fans cease operation. Traditional louver boards are fixed on fans, so that when the electronic device is rotated to change its position, the fans or the louver boards must be disassembled then fixed again according to the position of the electronic device.

### BRIEF DESCRIPTION OF THE DRAWINGS

Implementations of the present technology will now be described, by way of example only, with reference to the attached figures.

FIG. 1 is an exploded, isometric view of an embodiment of a thermal module with a plurality of louvers.

FIG. 2 is an exploded, isometric view of one of the louvers in FIG. 1.

FIG. 3 is an assembled, isometric view of the louver of FIG. 2.

FIG. 4 is an assembled, isometric view of FIG. 1.

FIG. 5 is a partially exploded, isometric view of an embodiment of an electronic device with the thermal module at a first working state.

FIG. 6 is an isometric partially exploded view of an embodiment of an electronic device similar to FIG. 5, but showing the electronic device positioned in a second working state.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “inside” indicates that at least a portion of a region is partially contained within a boundary formed by the object. The term “comprising” when utilized, means “including, but not necessarily limited to”; it specifically indicates open-ended inclusion or membership in the so-described combination, group, series and the like.

The present disclosure is described in relation to a thermal module 100 and an electronic device having the thermal module 100.

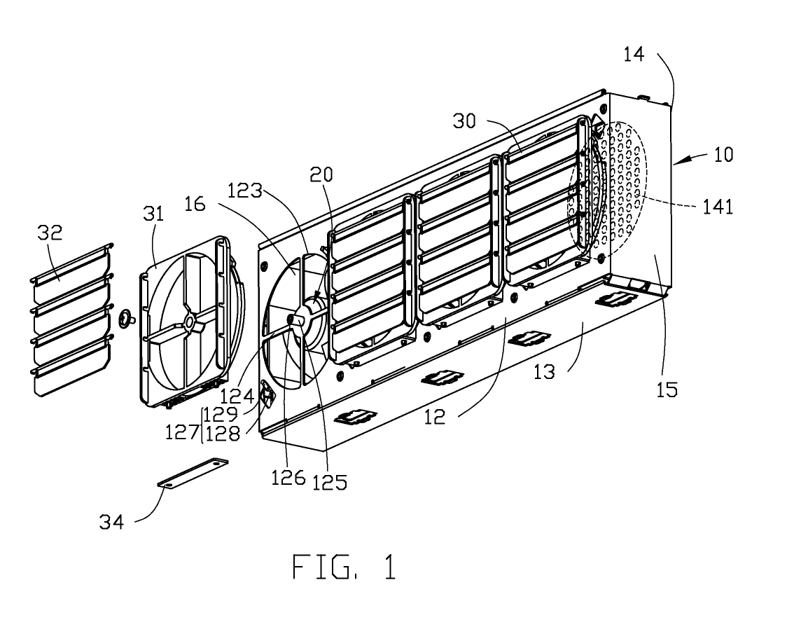

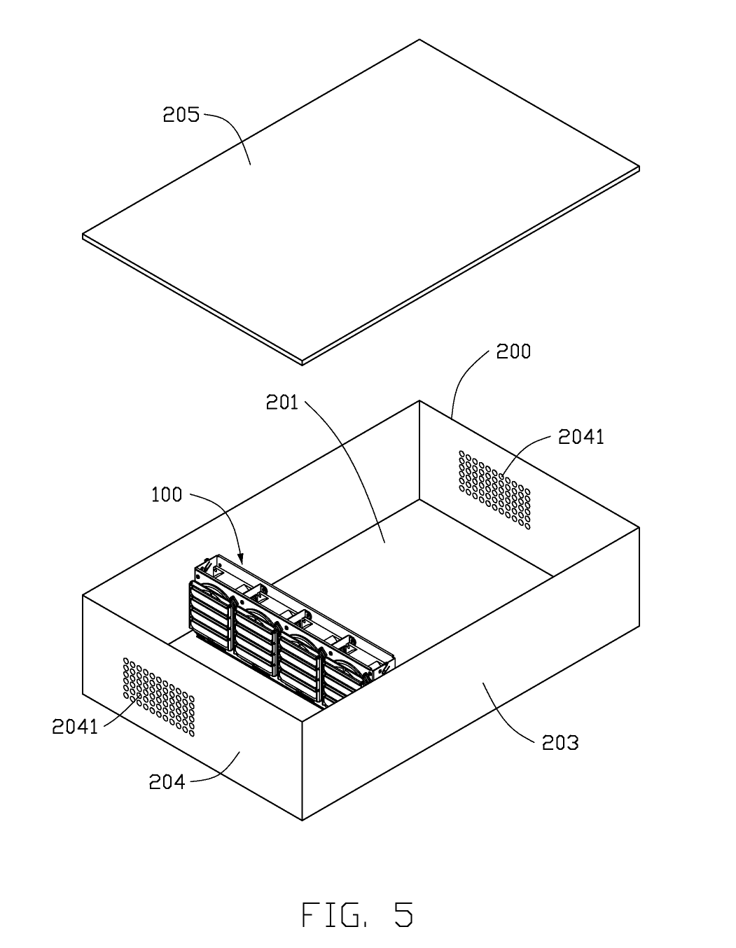

FIG. 1 illustrates an exploded view of the thermal module 100 for cooling the electronic device. FIG. 5 illustrates the electronic device comprises a rectangular enclosure 200 comprising a base board 201, two opposite side boards 203 coupled to the base board 201, two opposite end boards 204 coupled to the base board 201 and the side boards 203, and a cover 205 coupled to the side boards 203 and the end boards 204. Each end board 204 comprises a vent portion 2041 configured to provide air flow.

The thermal module 100 comprises a shell 10, a plurality of fans 20 assembled in the shell 10, and a plurality of louvers 30.

The shell 10 is substantially rectangular and comprises a front plate 12, a base plate 13, a rear plate 14, and two end plates 15. The rear plate 14 is opposite and substantially parallel to the front plate 12. The two end plates 15 are opposite and parallel to each other and coupled to the front plate 12 and the rear plate 14. The base plate 13 is coupled to bottom edges of the front plate 12, the rear plate 14, and the two end plates 15. The front plate 12, the base plate 13, the rear plate 14, and the two end plates 15 cooperatively define a mounting cavity 16. The front plate 12 defines a plurality of circular vents 123. A first cross 124 is located in each vent 123. A positioning post 125 extends outward from a center of the first cross 124, and the positioning post 125 axially defines a screw hole 126. The rear plate 14 defines a plurality of vent holes 141 corresponding to the vents 123. Two opposite L-shaped guiding plates 127 are configured adjacent to each vent 123. Each guiding plate 127 comprises an extension 128 perpendicularly extending from the front plate 12 and a guiding portion 129 extending to the corresponding vent 123 from an end of the extension 128. The fans 20 can be assembled in the mounting cavity 16 along the length. Each of the fans 20 directly faces one of the vents 123.

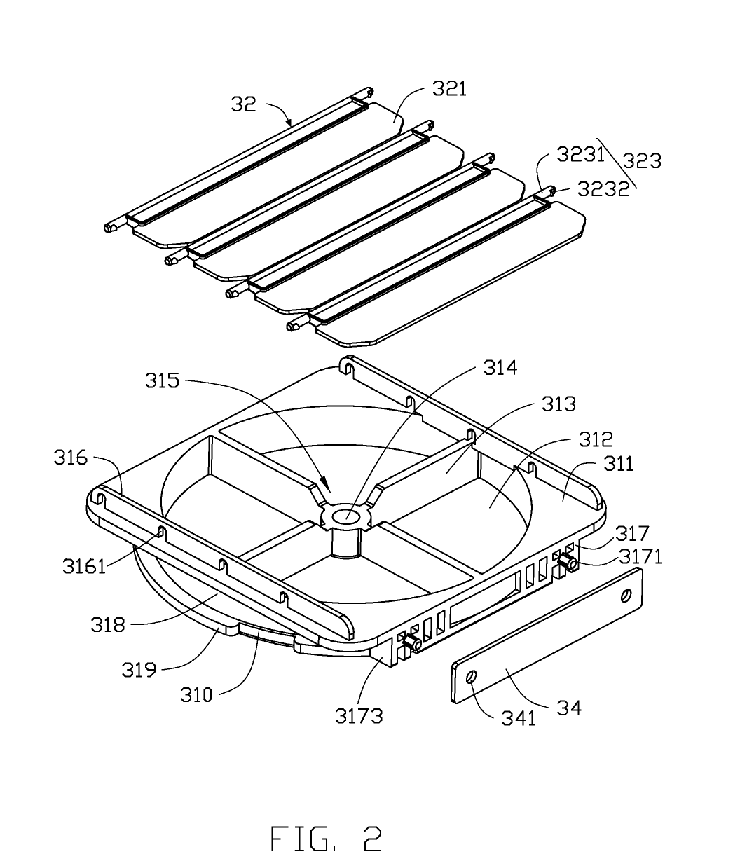

FIG. 2 illustrates that each louver 30 comprises a frame 31, a plurality of louver boards 32, and a sagging block 34.

The frame 31 comprises a positioning plate 311 defining a circular vent aperture 312 and includes a second cross 313. A center of the second cross 313 defines a through hole 314. A recess 315 extends from a top surface of the second cross 313 around the through hole 314. Two mounting strips 316 are configured on the positioning plate 311 adjacent to two opposite edges. A plurality of mounting holes 3161 are defined on a first end and a middle portion of each mounting strip 316. A height of each mounting hole 3161 is slightly greater than a width of each mounting hole 3161. A guiding loop 318 extends downwards from the positioning plate 311 around the vent aperture 312. A flange 319 extends outward from the guiding loop 318. Two opposite notches 310 are defined on the flange 319. A connecting block 317 is configured on an end of the positioning plate 311 adjacent to second ends of the mounting strips 316. The connecting block 317 is coupled to the guiding loop 318 and the flange 319. Two fastening pillars 3171 protrude from the connecting block 317. Two resisting portions 3173 extend from two ends of the connecting block 317.

Each of the louver boards 32 comprises a substantially rectangular board 321 and a shaft 323 extending outward along a longer edge. Two ends of the shaft 323 respectively comprise a shaft portion 3231 and a limiting portion 3232 extending parallel to the board 321.

The sagging block 34 is substantially rectangular and defines two fastening holes 341.

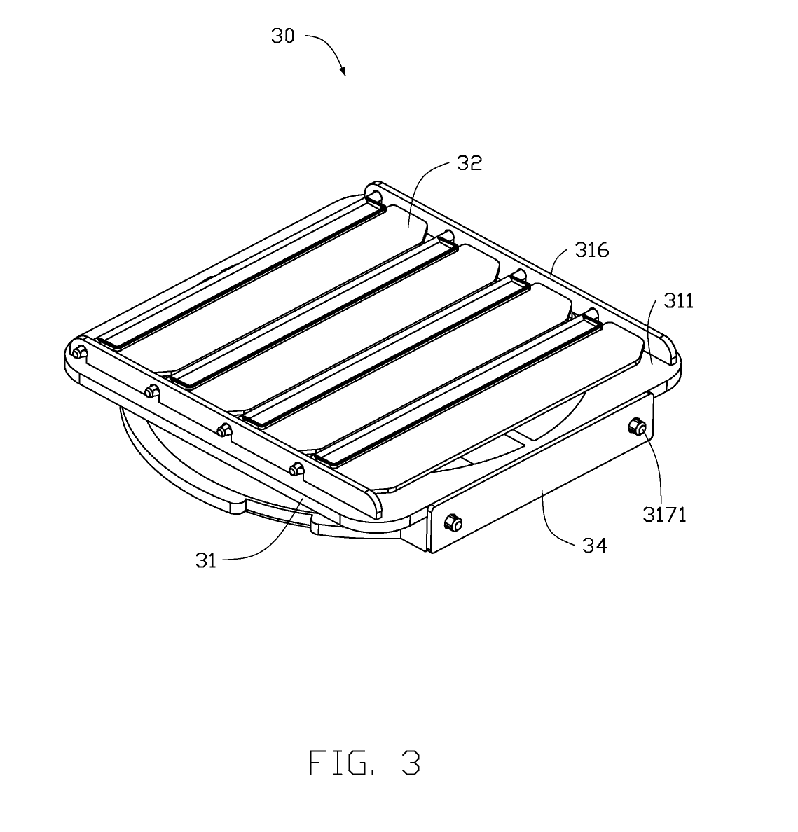

FIG. 3 illustrates an assembled view of the louver 30. In assembly, the sagging block 34 can be placed adjacent to the connecting block 317. The fastening pillars 3171 can engage in the fastening holes 341. Each of the louver boards 32 can be placed between and perpendicular to the mounting strips 316. The two shaft portions 3231 can be orderly extended and be received in two opposite mounting holes 3161 of the two mounting strips 316. In the illustrated embodiment, the limiting portions 3232 are located outside of the mounting strips 316 for preventing the shaft 3231 from being moved out of the mounting holes 3161. The louver boards 32 are rotatably assembled to the frame 31 and can together be closed to cover the vent aperture 312.

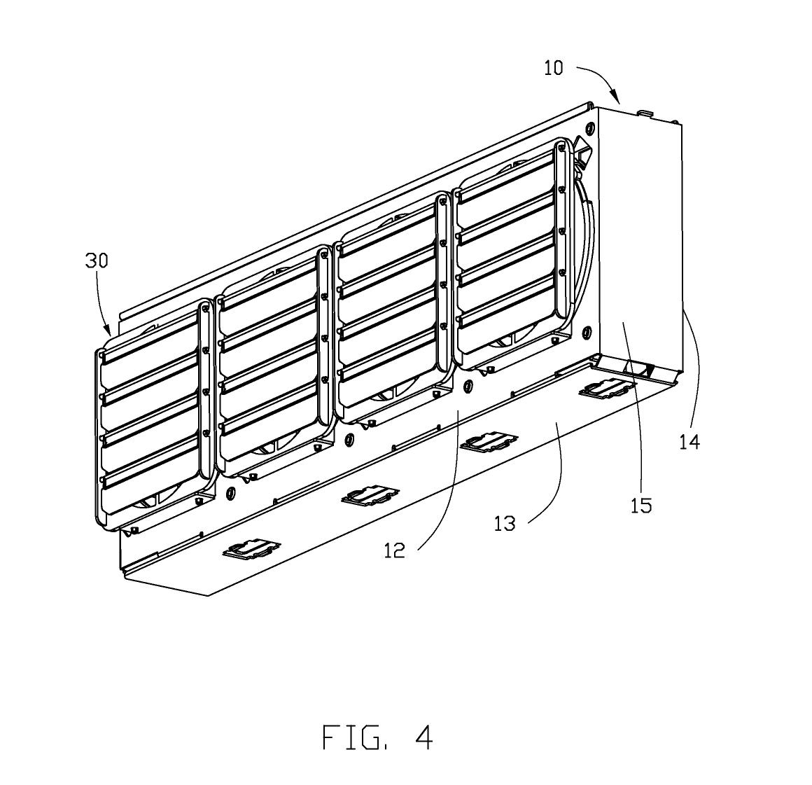

FIG. 4 illustrates an assembled view of the thermal module 100. In assembly, each louver 30 can be placed adjacent to the front plate 12, with the sagging block 34 adjacent to the base plate 13, the through hole 314 directly faces the positioning post 125, and the notches 310 directly face the guiding plates 127. Each louver 30 is moved to extend the guiding portion 129 through the corresponding notches 310 and extend the positioning posts 125 through the through holes 314. A plurality of screws 90 can engage in the screw holes 126 with heads of the screws 90 received in the recesses 315 and abutting the second cross 313. The flanges 319 are slidably received between the guiding portion 129 and the front plate 12. The frames 31 are rotatably assembled to the shell 10.

FIG. 5 illustrates the electronic device at a working state. In use, the thermal module 100 is assembled in the enclosure 200, with the base plate 13 being fixed on the base board 201 and the louvers 30 facing one of the end boards 204. When the electronic device is flatly placed, the base board 201 is supported by a flat surface. The frames 31 are rotated by the gravity of the sagging blocks 34. Then, the sagging blocks 34 face the base board 201 and the shafts 323 are parallel to the base board 201. When the fans 20 operate, the louver boards 32 are opened by airflow of the fans 20. Hot air of the electronic device flows through the vent holes 141, the fans 20, the vent aperture 312, and the vent portion 2041 to the external environment. When one of the fans 20 breaks down, the louver boards 32 corresponding to the fan 20 are closed by gravity, preventing hot air from entering.

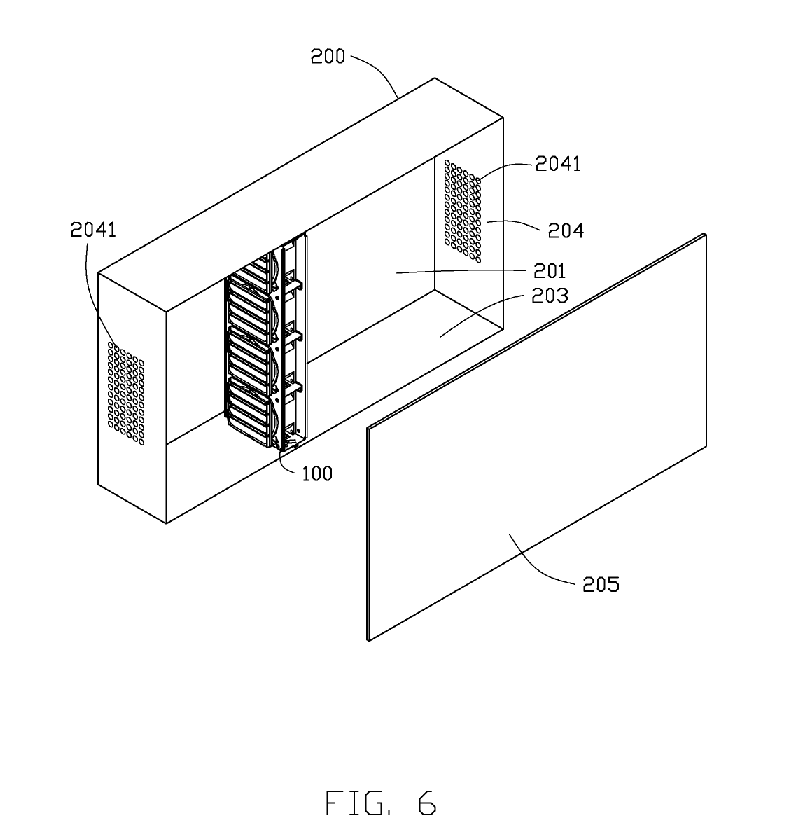

FIG. 6 illustrates the electronic device in another working state. When the electronic device is placed vertical, one of the side boards 203 is supported by the flat surface. The frames 31 are rotated by gravity of the sagging blocks 34, with the guiding loop 318 relatively sliding with the guiding plates 127. Then, the sagging blocks 34 face the side board 203 and the shafts 323 are parallel to the side board 203. The louver boards 32 are perpendicular to the base board 201, closing the vent aperture 312. When the fans 20 operate, the louver boards 32 are opened by airflow of the fans 20. Hot air of the electronic device flows through the vent holes 141, the fans 20, the vent aperture 312, and the vent portion 2041 to the external environment. When one of the fans 20 breaks down, the louver boards 32 corresponding to the fan 20 are closed by gravity, preventing the backflow of the hot air.

In a second embodiment, the sagging blocks 34 can be omitted, the first end and the middle portion of each mounting strips 316 define a plurality of mounting holes 3161. An end of each frame 31 adjacent to a second end of the mounting strips 316 can be solid and other portions of the frame 31 can be hollow, configuring a gravity center at the end.

In a third embodiment, the sagging blocks 34 can be omitted, the first end and the middle portion of each mounting strips 316 define a plurality of mounting holes 3161. An end of each frame 31 adjacent to the second end of the mounting strips 316 is made of materials different from that of other portions of the frame 31, defining the gravity center at the end.

As detailed above, the thermal module 100 has the frame 31 rotatably coupled to the shell 10 for receiving the fans 20 and the gravity center of the frame 31 defined away from the shafts 323 coupled to the frame 31, keeping the louver boards 32 flat while at rest.

The embodiments shown and described above are only examples. Many details are well known by those in the art therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A thermal module comprising:
a shell defining a plurality of vents;
a plurality of fans configured to be mounted in the shell and each of the plurality of fans corresponding to one of the plurality of vents; and
a plurality of louvers, each of the plurality of louvers comprising a frame rotatably coupled to one of the plurality of vents, a plurality of louver boards coupled to the frame, and a shaft extending from a side edge of each air shield and rotatably coupled to two opposite sides of the frame;
wherein the frame has a center of gravity adjacent to an end of the frame and away from the shaft.

2. The thermal module of claim 1, wherein each frame comprises a positioning plate defining a vent aperture and directly facing the corresponding vent, a second cross coupled to the positioning plate configured in the vent aperture and rotatably coupled to the corresponding vent.

3. The thermal module of claim 2, wherein a first cross is located in each vent, and a positioning post defining a screw hole extends from a center of the first cross, a center of the second cross defines a through hole for receiving the positioning post, a screw engages in the screw hole and a head of the screw abuts the second cross.

4. The thermal module of claim 2, wherein two mounting strips are configured on the positioning plate adjacent to two opposite edges of the positioning plate, each air shield comprises a board, the shaft extends from a longer edge of the board, and two ends of the shaft are respectively rotatably coupled to the mounting strips.

5. The thermal module of claim 4, wherein a guiding plate configured adjacent to one of the vents is slidably coupled to a guiding loop extending downwards from the positioning plate.

6. The thermal module of claim 5, wherein the guiding plate comprises an extension perpendicularly extending from the front plate and a guiding portion extending to the corresponding vent from an end of the extension, a flange extending outward from the guiding loop is capable of being received between the guiding portion and the front plate.

7. The thermal module of claim 4, wherein first ends and middle portions of each mounting strip defines a plurality of mounting holes, each shaft comprises two shaft portions and two limiting portions, the two shaft portions are received in two opposite mounting holes of the mounting strips and the limiting portions prevent the shaft portions from being out of the mounting holes.

8. The thermal module of claim 1, wherein an end of the frame, which is adjacent to a side of each air shield away from the shaft, is configured to be coupled to a sagging block, keeping the louver boards always being flat while at rest.

9. The thermal module of claim 1, wherein an end of the frame, which is adjacent to a side of each air shield away from the shaft, is configured to be solid and other portions of the frame is configured to be hollow, making the louver boards always being flat while at rest.

10. The thermal module of claim 1, wherein an end of the frame, which is adjacent to a side of each air shield away from the shaft, is configured to be made of materials different from that of other portions of the frame, making the louver boards always being flat while at rest.

11. An electronic device comprising:
an enclosure comprising two vent portions located on two opposite ends of the enclosure; and
a thermal module comprising:
a shell configured to be mounted in the enclosure and defining a plurality of vents;
a plurality of fans configured to be mounted in the shell and each of the plurality of fans corresponding to one of the plurality of vents and one of the two vent portions; and
a plurality of louvers, each of the plurality of louvers comprising a frame rotatably coupled to one of the plurality of vents, a plurality of louver boards coupled to the frame, and a shaft extending from a side edge of each air shield and rotatably coupled to two opposite sides of the frame;
wherein the frame has a center of gravity adjacent to an end of the frame and away from the shaft; and
wherein the enclosure changes its placed state, each frame is rotated by gravity to the end of the frame being bottom.

12. The electronic device of claim 11, wherein each frame comprises a positioning plate defining a vent aperture and directly facing the corresponding vent, a second cross coupled to the positioning plate is located in the vent aperture and rotatably coupled to the corresponding vent.

13. The electronic device of claim 12, wherein a first cross is located in each vent, and a positioning post defining a screw hole extends from a center of the first cross, a center of the second cross defines a through hole for receiving the positioning post, a screw engages in the screw hole and a head of the screw urges the second cross.

14. The electronic device of claim 12, wherein two mounting strips are configured on the positioning plate adjacent to two opposite edges of the positioning plate, each air shield comprises a board, the shaft extends from a longer edge of the board, and two ends of the shaft are respectively rotatably coupled to the mounting strips.

15. The electronic device of claim 14, wherein a guiding plate configured adjacent to one of the vents is slidably coupled to a guiding loop extending downwards from the positioning plate.

16. The thermal module of claim 15, wherein the guiding plate comprises an extension perpendicularly extending from the front plate and a guiding portion extending to the corresponding vent from an end of the extension, a flange extending outward from the guiding loop is capable of being received between the guiding portion and the front plate.

17. The electronic device of claim 14, wherein first ends and middle portions of each mounting strip defines a plurality of mounting holes, each shaft comprises two shaft portions and two limiting portions, the two shaft portions are received in two opposite mounting holes of the mounting strips and the limiting portions prevent the shaft portions from being out of the mounting holes.

18. The electronic device of claim 11, wherein an end of the frame, which is adjacent to a side of each air shield away from the shaft, is configured to be coupled to a sagging block, making the louver boards always being flat while at rest.

19. The electronic device of claim 11, wherein an end of the frame, which is adjacent to a side of each air shield away from the shaft, is configured to be solid and other portions of the frame is configured to be hollow, making the louver boards always being flat while at rest.

20. The electronic device of claim 11, wherein an end of the frame, which is adjacent to a side of each air shield away from the shaft, is configured to be made of materials different from that of other portions of the frame, making the louver boards always being flat while at rest.
